(19) United States
(12) Patent Application Publication
(10) Pub. No.: US 2007/0128826 A1
(43) Pub. Date: Jun. 7, 2007

(54) ARTICLE WITH MULTILAYERED COATING AND METHOD FOR MANUFACTURING SAME

(75) Inventor: GA-LANE CHEN, Santa Clara, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,554

(22) Filed: Aug. 21, 2006

(30) Foreign Application Priority Data
Dec. 2, 2005 (CN) 200510102017.9

(51) Int. Cl. H01L 21/00; H01L 29/82; H01L 21/30

(52) U.S. Cl. 438/455; 438/62; 257/414

(57) ABSTRACT

An exemplary article with a multilayered coating includes a substrate, an adhesive layer, a silicon layer, a silicon carbide layer, a blended layer of silicon carbide and carbon, and a hydrogenated DLC layer. The adhesive layer is formed on the substrate. The silicon layer is formed on the adhesive layer. The silicon carbide layer is formed on the silicon layer. The blended layer is formed on the silicon carbide layer. The hydrogenated diamond-like layer is formed on the blended layer. A material of the adhesive layer is selected from the group consisting of chromium and chromic silicide.

### FIELD OF THE INVENTION

The present invention generally relates to articles with multilayered coatings, and more particularly to an article with a multilayered coating and a method for manufacturing the article.

### DESCRIPTION OF RELATED ART

Diamond-like carbon (DLC) film deposition was first carried out by Aisenberg et al. Since this initial investigation of depositing DLC film, a variety of different techniques involving DLC films have been developed.

DLC usually consist of metastable amorphous material but can include a microcrystalline phase. DLC can contain both sp2 and sp3 hybridised carbon atoms. DLC can include amorphous carbon (a-C) and hydrogenated amorphous carbon (a-C:H) containing a significant sp3 bonding. Amorphous carbon where bonding consists of 85% sp3 bonding is called highly tetrahedral amorphous carbon (ta-C). Sp3 bonding provides valuable diamond-like properties such as mechanical hardness, low friction, optical transparency and chemical inertness onto a DLC film. DLC film has many advantages, such as being exhibiting deposition at room temperature, deposition onto steel or plastic substrates and superior surface smoothness.

Because of excellent properties such as corrosion resistance and wear resistance, DLC film is a suitable protective film material for various articles such as molds, cutting tools and hard disks. However, DLC film also has several drawbacks, one of the most serious practical problems being its poor adhesion to substrates. This difficulty is caused by the high compressive stresses present in DLC film and the high compressive residual stresses present between DLC film and the substrate. Due to this problem, commercial application of DLC film is restricted to a certain extent.

It is therefore desirable to find an article with a multilayered coating and a related manufacturing method which can overcome the above mentioned problems.

### SUMMARY OF THE INVENTION

In a preferred embodiment, an article with a multilayered coating includes a substrate, an adhesive layer, a silicon layer, a silicon carbide layer, a blended layer of silicon carbide and carbon, and a hydrogenated DLC layer. The adhesive layer is formed on the substrate. The silicon layer is formed on the adhesive layer. The silicon carbide layer is formed on the silicon layer. The blended layer is formed on the silicon carbide layer. The hydrogenated DLC layer is formed on the blended layer. A material of the adhesive layer is selected from the group consisting of chromium and chromic silicide.

### BRIEF DESCRIPTION OF THE DRAWINGS

Many aspects of embodiments can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a schematic cross-sectional view of an article with a multilayered coating according to a preferred embodiment; and

FIG. 2 is a schematic view of a multi-target co-sputtering apparatus for manufacturing the article with the multilayered coating of FIG. 1.

### DETAILED DESCRIPTION OF THE INVENTION

Embodiments will now be described in detail below with reference to the drawings.

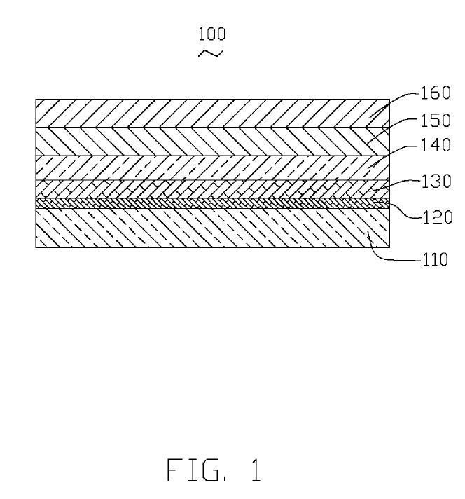

Referring to FIG. 1, an article with a multilayer coating 100 is shown. The article 100 includes a substrate 110, an adhesive layer 120, a silicon layer 130, a silicon carbide layer 140, a blended layer of silicon carbide and carbon 150, and a hydrogenated DLC layer 160.

The material of the substrate 110 is selected from the group consisting of: iron carbon chromium (Fe—C—Cr) alloy, iron carbon chromium molybdenum (Fe—C—Cr—Mo) alloy, iron carbon chromium silicon (Fe—C—Cr—Si) alloy, iron carbon chromium nickel molybdenum (Fe—C—Cr—Ni—Mo) alloy, iron carbon chromium nickel titanium (Fe—C—Cr—Ni—Ti) alloy, iron carbon chromium tungsten manganese (Fe—C—Cr—W—Mn) alloy, iron carbon chromium tungsten vanadium (Fe—C—Cr—W—V) alloy, iron carbon chromium molybdenum vanadium (Fe—C—Cr—Mo—V) alloy, and iron carbon chromium molybdenum vanadium silicon (Fe—C—Cr—Mo—V—Si) alloy. The substrate 110 is treated by mirror polishing in such a manner that the roughness of the substrate surface is less than 10 nm (nanometers).

The adhesive layer 120 is configured for increasing the adhesion of the other layers to the substrate 110. A material of the adhesive layer 120 is selected from the group consisting of chromium and chromium silicide. In this embodiment, the material of the adhesive layer 120 can be chromium. A thickness of the adhesive layer 120 can be in a range from 2 nm to 8 nm, and preferably from 4 nm to 6 nm.

The thickness of the silicon layer 130 can be in a range from 2 nm to 8 nm, and is preferably from 4 nm to 6 nm.

The thickness of the silicon carbide layer 140 can be in a range from 20 nm to 100 nm, and is preferably from 40 nm to 80 nm.

The thickness of the blended layer 150 can be in a range from 20 nm to 100 nm, and is preferably from 40 nm to 80 nm.

The thickness of the hydrogenated DLC layer 160 can be in a range from 20 nm to 3000 nm, and is preferably from 100 nm to 2000 nm.

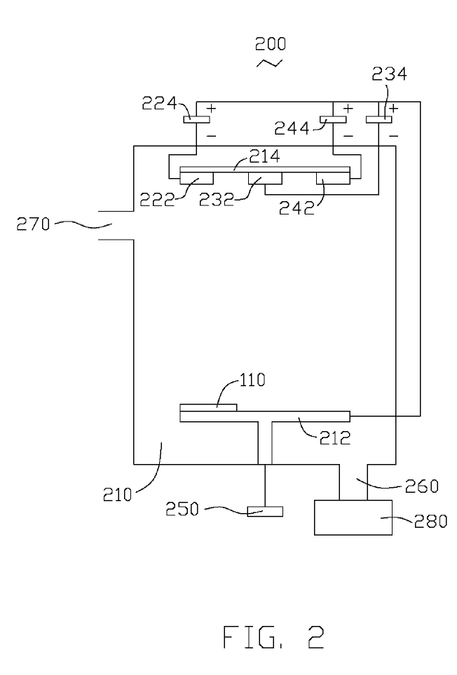

The article 100 can be manufactured using a co-sputtering method. Referring to FIG. 2, a multi-target co-sputtering apparatus 200 for manufacturing the article 100 according to the preferred embodiment is shown.

The multi-target co-sputtering apparatus 200 includes an airproof chamber 210 with a gas inlet 270 and a gas outlet 260, a sputtering source 214 in the chamber 210, a stage 212 in the chamber 210, a bias power supply 250, a pump system 280, and radio frequency (RF) power supplies 224, 234, and 244. The gas outlet 260 is connected with the pump system 280.

The stage 212 is configured (i.e. structured and arranged) for mounting the substrate 110 of the article 100 thereon. The stage 212 is configured to be rotatable about an axis. The substrate 110 may be rotatably mounted on the stage 212 such that the substrate 101 can rotate together with the stage 212 and also rotate about its own axis. The sputtering source 214 is spaced apart from and faces the stage 212. The sputtering source 214 rotates about an axis. The sputtering source 214 includes a first sputtering target 222, a second sputtering target 232, and a third sputtering target 242. The material of the first sputtering target 222 is chromium. The material of the second sputtering target 232 is silicon or silicon carbide. The material of the third sputtering target 242 is graphite.

Cathode of the power supply 224 is connected with the first sputtering target 222. Cathode of the power supply 234 is connected with the second sputtering target 232. Cathode of the power supply 244 is connected with the third sputtering target 242. Each anode of the power supplies 224, 234, and 244 is connected with the stage 212. Each power supply 224, 234, and 244 has a frequency of 13.56 MHZ.

The bias power supply 250 is connected with the stage 212 and configured for accelerating a depositing rate on the substrate 110 of positive ions. The bias power supply 250 can be direct current (DC) power or alternating current (AC) power. The bias power supply 250 is AC power in this embodiment. The frequency of the AC power can be in a range from 20 KHZ to 80 KHZ, and is preferably from 40 KHZ to 400 KHZ. The voltage of the AC power can be in a range from −100 volts to −30 volts, and is preferably from −60 volts to −40 volts.

The chamber 210 is filled with working gas. The working gas should be essentially unreactive with the substrate 110, sputtering target 222, 232, and 242, and all layers of the article 100. The working gas can be an inert gas, for example, argon gas, and krypton gas.

The method for manufacturing the article 100 using the multi-target co-sputtering apparatus 200 includes the steps of:
(1) providing a substrate;
(2) forming an adhesive layer on the substrate;
(3) forming a silicon layer on the adhesive layer;
(4) forming a silicon carbide layer on the silicon layer;
(5) forming a blended layer of silicon carbide and carbon on the silicon carbide layer; and
(6) forming a hydrogenated DLC layer on the blended layer.

With references of FIGS. 1 and 2, the method for manufacturing the article 100 will be described in more detail as follows.

In step 1, a substrate 110 is provided.

In step 2, an adhesive layer 120 is formed on the substrate 110. A material of the adhesive layer 120 is selected from the group consisting of chromium and chromium silicide. In this embodiment, the material of the adhesive layer 120 is chromium. Step 2 includes the following the steps of: evacuating the chamber 210 through gas outlet 260 using the pump system 280; filling the chamber 210 with argon gas through gas inlet 270; rotating the sputtering source 214 or the stage 212 in a manner such that the substrate 110 aligns with the first sputtering target 222; turning on the power supply 224 while keeping power supplies 234 and 244 off; forming an adhesive layer 120 on the substrate 110. Due to the operation of the power supply 224 between the stage 212 and the first sputtering target 222, glow discharge takes place in the argon gas and positive argon ions are produced. The argon ions are accelerated towards the first sputtering target 222 due to the voltage between the substrate 110 and the first sputtering target 222. The argon ions strike the first sputtering target 222 and then the kinetic energy of the argon ions is transferred to atoms in the first sputtering target 222. When the atoms obtain enough kinetic energy, they escape from the first sputtering target 222 and are then deposited onto the substrate 110. Thus the adhesive layer 120 is formed on the substrate 110.

The thickness of the adhesive layer 120 can be controlled by adjusting the sputtering time. The thickness of the adhesive layer 120 can be in a range from 2 nm to 8 nm, and is preferably from 4 nm to 8 nm. In the sputtering process, the substrate 110 rotates about its own axis in such a manner that the adhesive layer 120 is formed evenly on the substrate 110. The rotating rate about its own axis of the substrate 110 can be in a range from 10 RPM (Revolutions per minute) to 200 RPM, preferably in a range from 20 RPM to 80 RPM.

In step 3, a silicon layer 130 is formed on the adhesive layer 120. Similar to the adhesive layer 120, the silicon layer 130 is formed by the following steps: rotating the sputtering source 214 or the stage 212 in a manner such that the substrate 110 aligns with the second sputtering target 232; turning on the power supply 234 while keeping power supplies 224 and 244 off; allowing glow discharge to take place between the second sputtering target 232 and the stage 212 and then forming the silicon layer 130 on the adhesive layer 120.

The material of the second sputtering target 232 can be silicon. The thickness of the silicon layer 130 can be controlled by adjusting the sputtering time. The thickness of the silicon layer 130 can be in a range from 2 nm to 8 nm, and is preferably from 4 nm to 8 nm. In the sputtering process, the substrate 110 rotates about its own axis in such a manner that the silicon layer 130 is formed evenly on the substrate 110. The rotating rate about its own axis of the substrate 110 can be in a range from 10 RPM to 200 RPM, and is preferably from 20 RPM to 80 RPM.

In step 4, a silicon carbide layer 140 is formed on the silicon layer 130. The silicon carbide layer 140 is formed in a manner similar to that of the silicon layer 130, but the material of the second sputtering target 232 can instead be silicon carbide. The silicon carbide layer 140 is formed by the following steps: rotating the sputtering source 214 or the stage 212 in a manner such that the substrate 110 aligns with the second sputtering target 232; turning on the power supply 234 while keeping power supplies 224 and 244 off; allowing glow discharge to take place between the second sputtering target 232 and the stage 212, and then forming the silicon carbide layer 140 on the silicon layer 130.

The thickness of the silicon carbide layer 140 can be controlled by adjusting the sputtering time. The thickness of the silicon carbide layer 140 can be in a range from 20 nm to 100 nm, and is preferably from 40 nm to 80 nm. In the sputtering process, the substrate 110 rotates about its own axis in such a manner that the silicon layer 130 is formed evenly on the substrate 110. The rotating rate about its own axis of the substrate 110 can be in a range from 10 RPM to 200 RPM, and is preferably from 20 RPM to 80 RPM.

In step 5, a blended layer of silicon carbide and carbon 150 is formed on the silicon carbide layer 140. The blended layer 150 is formed in a manner similar to that of the silicon carbide layer 140, but using the second sputtering target 232 and the third sputtering target 242 together. During the sputtering process, the power supplies 234 and 244 are both kept on while the power supply 224 is off. Glow discharges take place between the second sputtering target 232 and the stage 212, and between the third sputtering target 242 and the stage 212. Thus the blended layer 150 is formed on the silicon carbide layer 140.

The thickness of the blended layer 150 can be controlled by adjusting the sputtering time. The thickness of the blended layer 150 can be in a range from 20 nm to 100 nm, and is preferably from 40 nm to 80 nm. In the sputtering process, the substrate 110 rotates about its own axis in such a manner that the blended layer 150 is formed evenly on the substrate 110. The rotating rate about its own axis of the substrate 110 can be in a range from 10 RPM to 200 RPM, and is preferably from 20 RPM to 80 RPM.

In step 6, a hydrogenated DLC layer 160 is formed on the blended layer 150. The hydrogenated DLC layer 160 is formed in a manner similar to that of the blended layer 150, but using a mix gas as the working gas. Before the sputtering process, the pressure in the chamber 210 is kept constant, part of the argon gas in the chamber 210 through the gas outlet 260 is removed using the pump system 280, and hydrogen source gas (e.g., gaseous hydrogen) is pumped into the chamber 210 through the gas inlet 270. Gas removal and pumping gas is halted until the volume ratio of the hydrogen source gas in the mix gas can be in a range from 5% to 20%. During the sputtering process, the power supply 244 is on while the power supplies 224 and 234 are off. Glow discharge takes place between the third sputtering target 242 and the stage 212, and then the hydrogenated DLC layer 160 is formed on the blended layer 150.

It should be noted that the hydrogen source gas in the mix gas can also include methane gas. The volume ratio of the methane gas in the mix gas can be in a range from 5% to 20%.

The thickness of the hydrogenated DLC layer 160 can be controlled by adjusting the sputtering time. The thickness of the hydrogenated DLC layer 160 can be in a range from 20 nm to 3000 nm, and is preferably from 100 nm to 2000 nm. In the sputtering process, the substrate 110 rotates about its own axis in such a manner that the hydrogenated DLC layer 160 is formed evenly on the blended layer 150. The rotating rate about its own axis of the substrate 110 can be in a range from 10 RPM to 200 RPM, and is preferably from 20 RPM to 80 RPM.

After step 6, the article with a multilayered coating 100 is formed. The article 100 includes a substrate 110, an adhesive layer 120, a silicon layer 130, a silicon carbide layer 140, a blended layer of silicon carbide and carbon 150, and a hydrogenated DLC layer 160.

It should be noted that the material of the adhesive layer 120 can include chromium silicide. Accordingly, a chromic silicide layer can be formed on the substrate 110 in step 2 of the above method. In this case, the material of the first sputtering target can be chromic silicide.

In the article 100, the adhesive layer 120 and the silicon layer 130 increase the adhesion of the later layers (i.e. the silicon carbide layer 140, the blended layer of silicon carbide and carbon 150, and the hydrogenated DLC layer 160) to the substrate 110. In addition, the silicon carbide layer 140 and the blended layer 150 increase the wear resistance of the article 100 due to the hardness of the silicon carbide. Furthermore, the hydrogenated DLC layer 160 enhances the release ability when the article 100 is a mold. The article 100 manufactured by the above method has the same characteristics.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. An article with a multilayered coating, comprising:
a substrate;
an adhesive layer formed on the substrate, the adhesive layer comprising a material selected from the group consisting of chromium and chromic silicide;
a silicon layer formed on the adhesive layer;
a silicon carbide layer formed on the silicon layer;
a blended layer formed on the silicon carbide layer, the blended layer comprising a combination of silicon carbide and carbon; and
a hydrogenated DLC layer formed on the blended layer.

2. The article as claimed in claim 1, wherein the substrate comprises a material selected from the group consisting of: iron carbon chromium alloy, iron carbon chromium molybdenum alloy, iron carbon chromium silicon alloy, iron carbon chromium nickel molybdenum alloy, iron carbon chromium nickel titanium alloy, iron carbon chromium tungsten manganese alloy, iron carbon chromium tungsten vanadium alloy, iron carbon chromium molybdenum vanadium alloy, and iron carbon chromium molybdenum vanadium silicon alloy.

3. The article as claimed in claim 1, wherein a thickness of the adhesive layer can be in a range from 2 nm to 8 nm.

4. The article as claimed in claim 3, wherein a thickness of the adhesive layer can be in a range from 4 nm to 6 nm.

5. The article as claimed in claim 1, wherein a thickness of the silicon layer can be in a range from 2 nm to 8 nm.

6. The article as claimed in claim 5, wherein a thickness of the silicon layer can be in a range from 4 nm to 6 nm.

7. The article as claimed in claim 1, wherein a thickness of the blended layer can be in a range from 20 nm to 100 nm.

8. The article as claimed in claim 7, wherein a thickness of the blended layer can be in a range from 40 nm to 80 nm.

9. The article as claimed in claim 1, wherein a thickness of the hydrogenated DLC layer can be in a range from 20 nm to 3000 nm.

10. The article as claimed in claim 1, wherein a thickness of the hydrogenated DLC layer can be in a range from 100 nm to 2000 nm.

11. A method for manufacturing an article with a multilayered coating thereon, comprising the steps of:
providing a substrate;
forming an adhesive layer on the substrate, the adhesive layer comprising a material selected from the group consisting of chromium and chromic silicide;
forming a silicon layer on the adhesive layer;
forming a silicon carbide layer formed on the silicon layer;
forming a blended layer on the silicon carbide layer, the blended layer comprising a combination of silicon carbide and carbon; and
forming a hydrogenated DLC layer on the blended layer.

12. The method as claimed in claim 11, wherein the adhesive layer is formed by sputtering.

13. The method as claimed in claim 11, wherein the silicon layer is formed by sputtering.

14. The method as claimed in claim 11, wherein the silicon carbide layer is formed by sputtering.

15. The method as claimed in claim 11, wherein the blended layer is formed by sputtering.

16. The method as claimed in claim 11, wherein the hydrogenated DLC layer is formed by sputtering.
